(19) United States
(12) Patent Application Publication
(10) Pub. No.: US 2026/0059843 A1
(43) Pub. Date: Feb. 26, 2026

(54) REMOVING HIGH-K LAYER FROM INNER SPACER

(71) Applicant: International Business Machines Corporation, Armonk, NY (US)

(72) Inventors: Ruilong Xie, Niskayuna, NY (US); HUIMEI ZHOU, Albany, NY (US); Julien Frougier, Albany, NY (US); Chanro Park, Clifton Park, NY (US); Min Gyu Sung, Latham, NY (US); Juntao Li, Cohoes, NY (US)

(21) Appl. No.: 18/809,519

(22) Filed: Aug. 20, 2024

(51) Int. Cl. H01L 29/51; H01L 29/06; H01L 29/417; H01L 29/423; H01L 29/66; H01L 29/775; H01L 29/786

(52) U.S. Cl. CPC H10D 64/691; H10D 30/014; H10D 30/43; H10D 30/6735; H10D 30/6757; H10D 62/121; H10D 64/017; H10D 64/018; H10D 64/258

(57) ABSTRACT

A semiconductor integrated circuit (IC) device includes a first source/drain region connected to a second source/drain region by a plurality of active channels, a backside contact that is directly coupled to the first source/drain region, a frontside contact that is directly coupled to the second source/drain region, and a backside dielectric plug that is directly coupled to the second source/drain region and that is directly coupled to the backside contact. In examples, every backside contact placeholder that is associated with a source/drain region that is connected to a frontside contact is removed and replaced by a respective backside dielectric plug. Relative to the backside contact placeholder, the replacement backside dielectric plug may reduce gate-drain Miller capacitance, source/drain capacitance, and may reduce leakage current between source and drain through substrate residue that may reside due to flawed substrate removal during backside processing.

### BACKGROUND

As demands to reduce the dimensions of transistor devices continue, the effects of parasitic capacitances between transistor regions may become more problematic.

### SUMMARY

In an embodiment of the disclosure, a semiconductor integrated circuit (IC) device is presented. The semiconductor IC device includes a replacement gate structure that includes a work function gate. The semiconductor IC device includes a high-κ layer directly connected with and between the work function gate and a nanolayer channel. The semiconductor IC device further includes an inner spacer directly connected to the work function gate.

In an embodiment of the disclosure, another semiconductor integrated circuit (IC) device is presented. The semiconductor IC device includes a high-κ layer directly connected to a top surface, to a bottom surface, to a front surface, and to a rear surface of a nanolayer channel. The semiconductor IC device includes a work function gate directly connected to the high-κ layer. The semiconductor IC device further includes an inner spacer with a bottom surface that is substantially coplanar with the top surface of the nanolayer channel and an inner sidewall that is directly connected to the work function gate.

In an embodiment of the disclosure, a semiconductor integrated circuit (IC) device fabrication method is presented. The method includes forming a high-κ layer within the gate trench around one or more active nanolayers, forming a gate trench sacrificial fill upon the high-κ layer filling the gate trench, and recessing a portion of the gate trench sacrificial fill and forming a gate mask in place thereof.

The above summary is not intended to describe each illustrated embodiment or every implementation or example of the present disclosure.

### BRIEF DESCRIPTION OF THE DRAWINGS

The drawings included in the disclosure are incorporated into, and form part of, the specification. They illustrate embodiments of the present disclosure and, along with the description, explain the principles of the disclosure. The drawings are only illustrative of certain embodiments and do not limit the disclosure.

FIG. 1 depicts a cross-section view of an illustrative semiconductor IC device in which a high-κ dielectric is absent from a sidewall of an inner spacer to allow for the inner spacer to be directly connected with a gate structure, according to one or more embodiments of the disclosure.

FIG. 2 depicts a partial structure top-down view of an illustrative semiconductor IC device in which a high-κ dielectric is absent from a sidewall of an inner spacer to allow for the inner spacer to be directly connected with a gate structure, according to one or more embodiments of the disclosure.

FIG. 3 through FIG. 16 depict various fabrication structure cross-section views of an illustrative semiconductor IC device in which a high-κ dielectric is absent from a sidewall of an inner spacer to allow for the inner spacer to be directly connected with a gate structure, according to one or more embodiments of the disclosure.

FIG. 17 depicts respective cross-section views of a traditional nanolayer transistor and an illustrative nanolayer transistor in which a high-κ dielectric is absent from a sidewall of an inner spacer to allow for the inner spacer to be directly connected with a gate structure, according to one or more embodiments of the disclosure.

FIG. 18 depicts a method of fabricating a semiconductor IC device in which a high-κ dielectric is absent from a sidewall of an inner spacer to allow for the inner spacer to be directly connected with a gate structure, according to one or more embodiments of the disclosure.

### DETAILED DESCRIPTION

The embodiments of the present disclosure relate to fabrication methods and resulting structures for semiconductor IC devices. More specifically, the present disclosure relates to fabrication methods and resulting semiconductor integrated circuit (IC) devices that include a backside dielectric plug that is formed to adequately electrically isolate, or disconnect, a portion of a channel (e.g., one or more nanolayer channels) from either its previously associated source region or drain region. This scheme may be utilized to modify transistors within a first region, such as a low power device region of a semiconductor IC device relative to transistors within a second region, such as a high performance region of the same semiconductor IC device while largely utilizing the same fabrication stages to form the various transistors.

A transistor is a type of microdevice that may be fabricated in semiconductor IC device front-end-of-line (FEOL) fabrication operations. Conventional transistors, or the like, incorporate planar field effect transistors (FETs) in which current flows through a semiconducting channel between a source and a drain, in response to a voltage applied to the gate. The semiconductor industry strives to obey Moore's law, which holds that each successive generation of integrated circuit devices shrinks to half its size and operates twice as fast. As device dimensions have shrunk, however, conventional silicon device geometries and materials have had trouble maintaining switching speeds without incurring failures such as, for example, leaking current from the device into the semiconductor substrate. Several new technologies emerged that allowed chip designers to continue shrinking transistor sizes. A FET generally is a transistor in which output current, i.e., source-drain current, is controlled by a voltage applied to an associated gate. A FET typically has three terminals, i.e., a gate structure, a source region, and a drain region. A gate structure is a structure used to control output current (i.e., flow of carriers in the channel) of a semiconducting device through electrical or magnetic fields. A channel is the region of the FET underlying the gate structure and between the source and drain of the semiconductor IC device that becomes conductive when the semiconductor device is turned on. The source is a doped region in the semiconductor IC device, in which majority carriers are flowing into the channel. A drain is a doped region in the semiconductor IC device located at the end of the channel, in which carriers are flowing out of the transistor through the drain.

One technology change modified the structure of the FET from a planar device to a three-dimensional device in which the semiconducting channel was replaced by a fin that extends out from the plane of the substrate. In such a device, commonly referred to as a FinFET, the control gate wraps around three sides of the fin to influence current flow from three surfaces instead of one. The improved control achieved with a 3D design results in faster switching performance and reduced current leakage. Building taller devices has also permitted increasing the device density within the same footprint that had previously been occupied by a planar FET.

The FinFET concept was further extended by developing a gate all-around FET, or GAA FET, in which the gate fully wraps around one or more channels for maximum control of the current flow therein. In the GAA FET, the channels can take the form of nanolayers, nanolayers, or the like, that are isolated from the substrate. In the GAA FET, channel surfaces are in respective contact with the source and drain and other respective channel surfaces are in contact with and surrounded by the gate.

The flowcharts and cross-sectional diagrams in the drawings illustrate a method of fabricating a semiconductor IC device, such as a processor, filed programmable gate array (FPGA), memory module, or the like. In some alternative implementations, the fabrication steps may occur in a different order than that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” if the relevant characteristics and functionalities of layer “A”and layer “B”are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the depicted structure(s) as oriented. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of ±8%, ±5%, ±2%, or the like, difference between the coplanar materials.

As used herein, the term “coplanar” refers to two surfaces that lie in a common plane. In other words, two surfaces are coplanar if there exists a geometric plane that contains all the points of both of the surfaces. Accordingly, two surfaces may be referred to as substantially coplanar despite deviations from coplanarity, so long as those deviations do not impact the desired result of the coplanarity.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, e.g., 5:1, 10:1 or 20:1.

For the sake of brevity, conventional techniques related to semiconductor IC device fabrication may or may not be described in detail and/or depicted herein. Moreover, the various tasks and process steps described herein can be incorporated into a more comprehensive procedure or process having additional steps or functionality not described and/or not depicted in detail herein. Various steps in the manufacture of semiconductor devices are well known and so, in the interest of brevity, many conventional steps will only be mentioned briefly herein, will be omitted entirely without providing the well-known process details, and/or will not be depicted.

In general, the various processes used to form a semiconductor IC device that may be packaged into an IC package fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain regions and uses electrons as the charge carrier. The pFET includes p-doped source and drain regions and uses holes as the charge carrier. Complementary metal oxide semiconductor (CMOS) is a technology that uses complementary and symmetrical pairs of p-type and n-type MOSFETs to implement logic functions. As mentioned above, hole mobility on the pFET may have an impact on overall device performance.

The wafer footprint of a FET is related to the electrical conductivity of the channel material. If the channel material has a relatively high conductivity, the FET can be made with a correspondingly smaller wafer footprint. A method of increasing channel conductivity and decreasing FET size is to form the channel as a nanostructure, such as a nano wire, nano ribbon, nanolayer, nanolayer, or the like, hereinafter referred to as a nanolayer. For example, a GAA FET provides a relatively small FET footprint by forming the channel region as a series of vertically stacked nanolayers. In a GAA configuration, a GAA FET includes a source region, a drain region and vertically stacked nanolayer channels between the source and drain regions. These devices typically include one or more suspended nanolayers that serve as the channel. A gate surrounds the stacked nanolayers and regulates electron flow through the nanolayers between the source and drain regions. GAA FETs may be fabricated by forming alternating layers of active nanolayers and sacrificial nanolayers. The sacrificial nanolayers are released from the active nanolayers before the FET device is finalized. For n-type FETs, the active nanolayers are typically silicon (Si) and the sacrificial nanolayers are typically silicon germanium (SiGe). For p-type FETs, the active nanolayers can be SiGe and the sacrificial nanolayers can be Si. In some implementations, the active nanolayers of a p-type FET can be SiGe or Si, and the sacrificial nanolayers can be Si or SiGe. Forming the nanolayers from alternating layers of active nanolayers formed from a first type of semiconductor material (e.g., Si for n-type FETs, and SiGe for p-type FETs) and sacrificial nanolayers formed from a second type of semiconductor material (e.g., SiGe for n-type FETs, and Si for p-type FETs) may provide for improved channel electrostatics control.

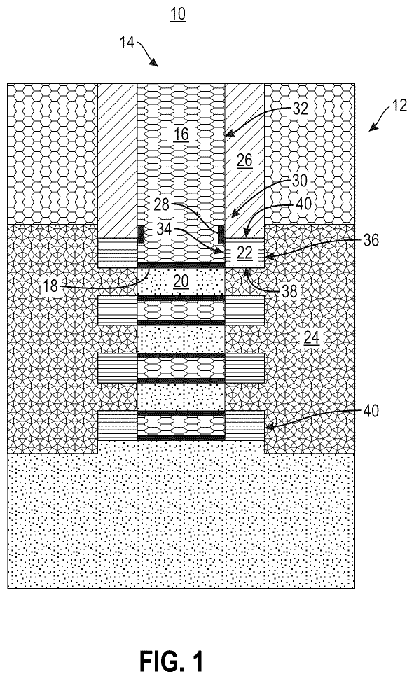

Referring now to the figures, FIG. 1 depicts a cross-sectional view of an illustrative semiconductor integrated circuit (IC) device 10 in which a high-κ dielectric is absent from a sidewall of an inner spacer to allow for the inner spacer to be directly connected with a gate structure. The structures or regions of the semiconductor IC device 10 may effectively form a GAA nanolayer transistor 12. The semiconductor IC device 10 includes a replacement gate structure 14 comprising a work function gate 16. The semiconductor IC device 10 further includes a high-κ dielectric layer 18 directly connected with and between the work function gate 16 and a nanolayer channel 20. The semiconductor IC device 10 further includes an inner spacer 22 directly connected to the work function gate 16.

In an example, the semiconductor IC device 10 further includes a source/drain region 24 directly connected with the nanolayer channel 20 and directly connected to the inner spacer 22. In an example, the semiconductor IC device 10 further includes a gate spacer 26 upon and directly connected to the inner spacer 22.

In an example, the semiconductor IC device 10 further includes a residual portion 28 of the high-κ layer directly upon a lower sidewall portion 30 of the gate spacer 26 between the gate spacer 26 and the work function gate 16. In an example, an upper sidewall portion 32 of the gate spacer 26 is directly connected to the work function gate 16.

In an example, the inner spacer 22 includes an inner sidewall 34 that is directly connected to the work function gate 16. In an example, the inner spacer 22 includes an outer sidewall 36 and a bottom surface 38 that is directly connected to the source/drain region 24.

In an example, the inner spacer 22 includes a top surface 40 that is directly connected to the gate spacer 26. In an example, the bottom surface 38 of the inner spacer 22 is substantially coplanar with a top surface of the nanolayer channel 20. In an example, the inner spacer 22 separates the work function gate 16 from the source/drain region 24.

In another embodiment of the present disclosure, another instance of the semiconductor IC device 10 is presented. The semiconductor IC device 10 includes the high-κ dielectric layer 18 directly connected to a top surface, to a bottom surface, to a front surface (e.g. in a cross-section plane out of the page), and to a rear surface (e.g. in a cross-section plane into the page) of the nanolayer channel 20. The semiconductor IC device 10 further includes the work function gate 16 directly connected to the high-κ dielectric layer 18. The semiconductor IC device 10 further includes the inner spacer 22 that includes the bottom surface 38 that is substantially coplanar with the top surface of the nanolayer channel 20 and the inner sidewall 34 that is directly connected to the work function gate 16.

In an example, the semiconductor IC device 10 further includes the source/drain region 24 directly connected to a side surface of the nanolayer channel 20 and directly connected to the bottom surface 38 of the inner spacer 22.

In an example, the semiconductor IC device 10 further includes the gate spacer 26 directly connected to the top surface 40 of the inner spacer 22. In an example, the semiconductor IC device 10 further includes the residual high-κ layer portion 28 upon the lower sidewall portion 30 of the gate spacer 26 and directly between the gate spacer 26 and the work function gate 16. In an example, the upper sidewall portion 32 of the gate spacer 26 is directly connected to the work function gate 16.

In an example, the inner spacer 22 further includes the outer sidewall 36 that is directly connected to the source/drain region 24. In an example, the inner spacer 22 separates the work function gate 16 from the source/drain region 24.

In the above illustrative embodiments, the semiconductor IC device 10 generally does not have a high-κ dielectric upon at least a portion of the inner sidewall 34. Therefore, a horizontal dimension 40 of dielectric material between the source/drain region 24 and the work function gate 16 is reduced. Consequently, the parasitic capacitance between the source/drain region 24 and the work function gate 16 is relatively reduced which may improve the performance of the semiconductor IC device 10 and may provide for further semiconductor IC device scaling.

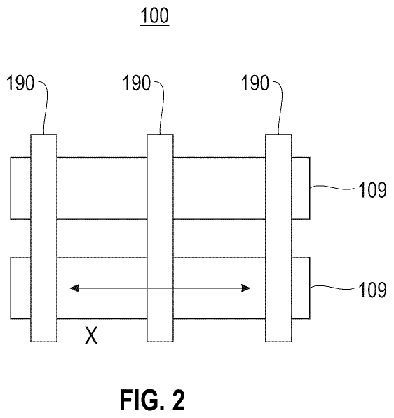

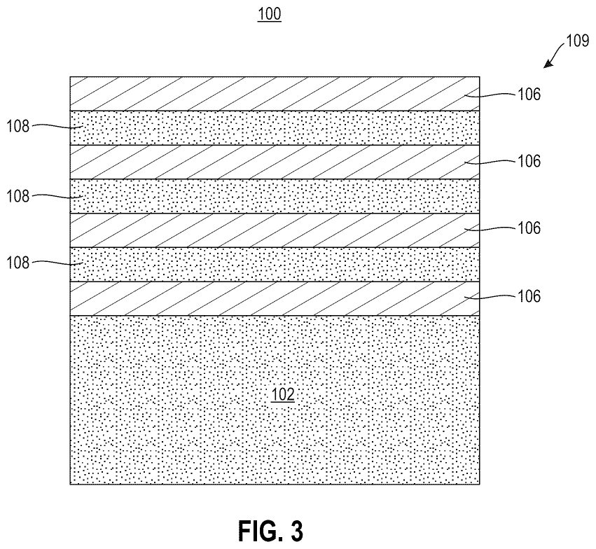

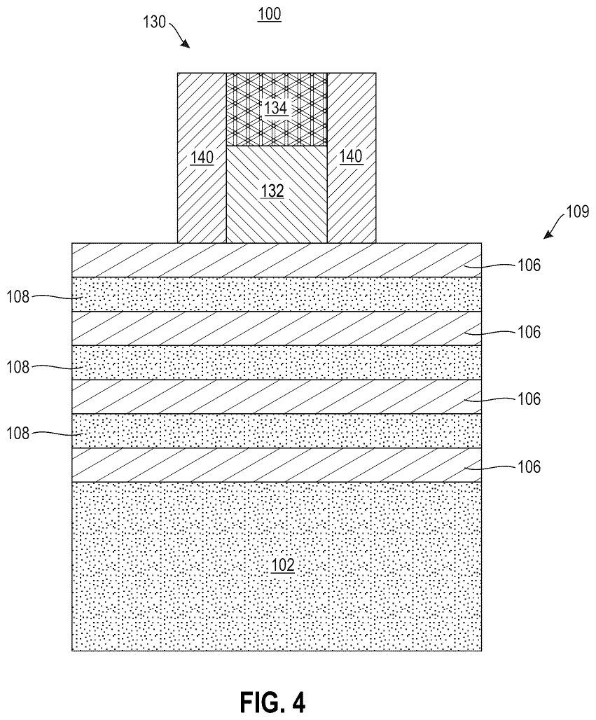

FIG. 2 depicts a partial top-down view of a semiconductor IC device 100 in which a high-κ dielectric is absent from a sidewall of an inner spacer to allow for the inner spacer to be directly connected with the gate structure, according to embodiments of the disclosure. As currently depicted, semiconductor IC device 100 includes a pair of nanolayer rows 109 and replacement gate structures 190. FIG. 2 also depicts a cross-sectional plane of the various cross-sectional views of FIG. 3 through FIG. 16. This X cross-sectional plane is through a nanolayer row 109 and across replacement gate structures 190.

FIG. 3 depicts a cross-sectional initial fabrication view of the semiconductor IC device 100. At this initial fabrication stage, the semiconductor IC device 100 may include a substrate structure 102, active nanolayers 108, and sacrificial nanolayers 106.

For clarity, the fabrication of the semiconductor IC device 100 at the present stage may utilize processes that may now be known or that may be developed in the future. For illustration purposes, a particular fabrication process to form semiconductor IC device 100 at the present stage is presented below. This illustrative methodology may be one of many that may achieve or result in the initial semiconductor IC device 100, as depicted. When components referenced in the illustrative methodology below are depicted in the Figures, such associated component numeral is expressly utilized. Otherwise, when components are generically referenced in the illustrative methodology that are not depicted, a component numeral is not denoted.

The illustrative semiconductor IC device 100 may be formed by initially providing or forming the substrate structure 102. The substrate structure 102 may be a bulk-semiconductor substrate. In one example, the bulk-semiconductor substrate may be a silicon-containing material. In another implementation, the substrate structure 102 includes an upper substrate, a lower substrate, and an etch stop layer between the upper substrate and the lower substrate. The upper substrate and the lower substrate may be comprised of any suitable semiconductor material(s), and the etch stop layer may be a dielectric material with etch selectivity to one or both upper substrate and/or the lower substrate. In one example, the etch stop layer may be an oxide and the substrate structure may be referred to as a buried oxide (BOX) substrate. In another example, the lower substrate may be composed of Si. The etch stop layer may be composed of Silicon Germanium (SiGe) and may be epitaxially grown from the top surface of lower substrate and the upper substrate may be composed of Si and may be epitaxially grown from the top surface of etch stop layer.

Next, the illustrative semiconductor IC device 100 may be formed by forming nanolayers over the substrate structure by forming a series of alternating sacrificial nanolayers 106 and active nanolayers 108. In certain examples, the bottommost sacrificial nanolayer 106 is initially formed directly on an upper surface of the substrate structure 102. In other examples, certain layer(s) may be formed between the upper surface of the substrate structure 102 and the bottommost sacrificial nanolayer 106.

The nanolayers may be formed by fabricating the alternating series of sacrificial nanolayers 106, such as SiGe sacrificial nanolayers, and active nanolayers 108, such as Si nanolayers. The sacrificial nanolayers 106 can have Ge percentages ranging from 20% to 45%. In an implementation, the alternating active sacrificial nanolayer 106 and active nanolayer 108 may be formed by epitaxially growing each layer until the desired number and desired thicknesses of the layers are achieved. Any number of alternating nanolayers can be provided. Epitaxial materials can be grown from gaseous or liquid precursors. For example, epitaxial materials can be grown using vapor-phase epitaxy (VPE), molecular-beam epitaxy (MBE), liquid-phase epitaxy (LPE), or other suitable processes.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a (100) orientated crystalline surface will take on a (100) orientation. In some embodiments, epitaxial growth and/or deposition processes are selective to forming on semiconductor surfaces, and generally do not deposit material on exposed surfaces, such as silicon dioxide or silicon nitride surfaces.

Although it is specifically contemplated that the sacrificial nanolayers 106 can be formed from SiGe and that the active nanolayers 108 can be formed from Si, it should be understood that any appropriate materials can be used instead, as long as the semiconductor materials have etch selectivity with respect to one or more of the others, as is consistent with the description of the fabrication stages herein. Although it is specifically contemplated that the sacrificial nanolayers 106 and the active nanolayers 108 are formed by epitaxial growth, such nanolayers can be formed by any appropriate deposition mechanism.

Further, in the depicted fabrication stage, the nanolayers may be patterned into nanolayer rows 109 (as depicted in FIG. 2), and STI regions (not shown) may be formed within the substrate structure 102 adjacent to the nanolayer rows 109.

The one or more nanolayer rows 109 may be formed by lithography and etching techniques. Following the nanolayer row 109 patterning process, the one or more nanolayer rows 109 are formed. The removal of undesired portion(s) of the nanolayers may further remove undesired portions of substrate structure 102 that are adjacent to respective footprints of nanolayer rows 109 to form STI region openings. A STI region may be formed upon and/or within the substrate structure 102 within respective STI region openings. The STI regions may be formed by depositing electrical dielectric material(s) within respective STI region opening(s). A top surface of the one or more STI regions may be initially coplanar with or below a top surface of the substrate structure 102.

FIG. 3 depicts cross-sectional views of the semiconductor IC device 100 after fabrication operations, in accordance with embodiments of the present disclosure. In the depicted fabrication stages, one or more sacrificial gate structure(s) 130 and gate spacers 140 may be formed.

The sacrificial gate structures 130 may include a sacrificial gate liner (not shown), a sacrificial gate 132, and a sacrificial gate cap 134. The sacrificial gate structures 130 may be formed by initially depositing a sacrificial gate liner (e.g., a dielectric, oxide, or the like) upon the one or more STI regions and upon and around the one or more nanolayer rows 109. The sacrificial gate structures 130 may further be formed by subsequently depositing a sacrificial gate layer (e.g., amorphous silicon, or the like) upon the sacrificial gate liner layer. The thickness of the sacrificial gate layer may be such that the top surface of the sacrificial gate layer is above the top surface of the one or more nanolayer rows 109. The sacrificial gate structures 130 may further be formed by forming a gate cap layer upon the sacrificial gate layer. The gate cap layer may be formed by depositing a mask material, such as a hard mask material, such as silicon nitride, silicon oxide, combinations thereof, or the like, upon the sacrificial gate layer. The gate cap layer may be composed of one or more layers of masking materials to protect the sacrificial gate layer and/or other underlying materials during subsequent processing of semiconductor IC device 100.

The one or more sacrificial gate structures 130 may further be formed by patterning the gate cap layer, sacrificial gate layer, and sacrificial gate liner by, for example, using lithography and etch processes to remove undesired portions and retain desired portion(s), respectively. The retained desired portion(s) of the gate cap layer, sacrificial gate layer, and sacrificial gate liner may form the sacrificial gate liner (not shown), the sacrificial gate 132, and the sacrificial gate cap 134, respectively, of each of the one or more sacrificial gate structures 130.

The gate spacer(s) 140 may be formed by a conformal deposition of a dielectric material, such as silicon nitride, SiBCN, SiNC, SiN, SiCO, SiNOC, or a combination thereof, or the like, upon STI regions, upon around the one or more sacrificial gate structures 130, and upon and around the one or more nanolayer rows 109. Subsequently, undesired portions of dielectric material may be removed while desired portions the dielectric material may be retained to thereby form the gate spacer(s) 140 located generally upon the sidewalls of the sacrificial gate structures 130.

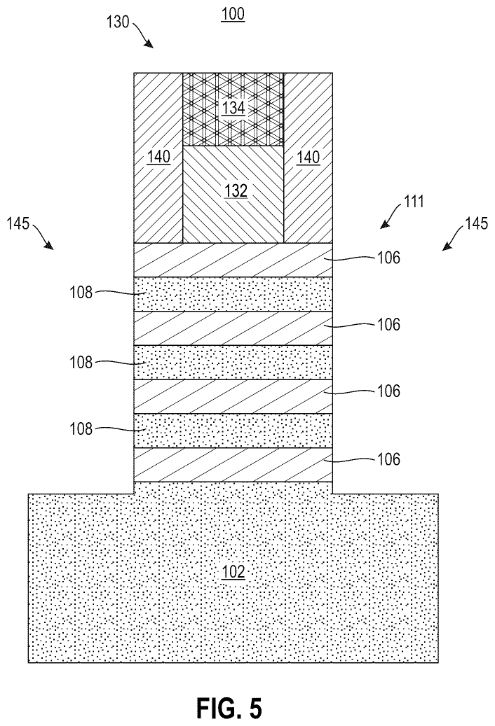

FIG. 5 depicts cross-sectional views of the semiconductor IC device 100 after fabrication operations, in accordance with embodiments of the present disclosure. In the depicted fabrication stages, source/drain canyons 145 may be formed.

The source/drain canyons 145 may be formed within the nanolayer rows 109 and within the substrate structure 102 between gate spacer(s) 140 of neighboring sacrificial gate structures 130. In other words, a single nanolayer row 109 may be separated, by one or more recesses, into multiple nanolayer stacks 111 each located underneath at a portion of respective sacrificial gate structure 130 and associated gate spacer(s) 140.

The source/drain canyons 145 may be formed between adjacent sacrificial gate structures 130 by removing respective portions of the sacrificial nanolayers 106 and active nanolayers 108 that are between gate spacer(s) 140 of adjacent or neighboring sacrificial gate structures 130. The source/drain canyons 145 may be formed to a depth to stop at the top surface or below the top surface of the substrate structure 102. The undesired portions of sacrificial nanolayers 106, active nanolayers 108, and the like, may be removed by etching or other subtractive removal techniques. As the gate spacer(s) 140 and the sacrificial gate structures 130 may be utilized to protect the underlying portions of sacrificial nanolayers 106, active nanolayers 108, respective sidewalls of the nanolayer stacks 111 may be substantially coplanar and/or substantially vertical with the outer sidewalls of the gate spacer(s) 140 there above.

As used herein, “substantially vertical” sidewalls deviate from a direction normal to a major surface (e.g., top surface, etc.) of the substrate structure 102 by less than 5°, e.g., 0°, 1°, 2°, 3°, 4°, or 5°, including ranges between any of the foregoing values.

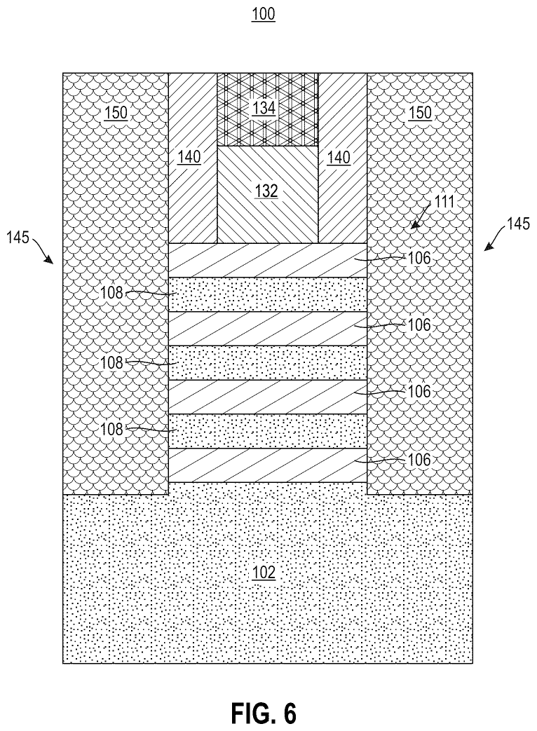

FIG. 6 depicts cross-sectional views of the semiconductor IC device 100 after fabrication operations, in accordance with embodiments of the present disclosure. In the depicted fabrication stages, respective sacrificial source/drain (S/D) regions 150 may formed upon the substrate structure 102.

The sacrificial S/D regions 150 may be formed by deposition of a blanket layer of sacrificial dielectric material upon the substrate structure 102 and upon the STI regions and a subsequent etch back or polish to expose the gate cap(s) 132 and planarize the top surface of the semiconductor IC device 100. Alternatively, the sacrificial S/D regions 150 may be formed by selective epitaxial grown of a sacrificial dielectric material from the substrate structure 102 within the source/drain canyons 145 with such growth occurring from the STI regions.

As used herein, a “sacrificial source/drain” region is a temporary region that serves as a mask, placeholder, and for structural integrity during subsequent fabrication stages and is later removed and replaced by a functional source/drain region.

The semiconductor material that provides each of the sacrificial S/D regions 150 may be composed of one of the semiconductor materials mentioned above for the semiconductor structure. For example, the semiconductor material that provides the sacrificial S/D regions 150 can be compositionally the same, or compositionally different from the sacrificial nanolayers 106. Generally, sacrificial S/D regions 150 may be composed of a material that has etch selectivity to the material(s) of the active nanolayers 108 and/or the substrate structure 102. For example, when the sacrificial nanolayers 106 are composed of SiGe, the sacrificial S/D regions 150 may also be composed of SiGe, with a substantially same or different percentage of Ge relative thereto.

The sacrificial S/D regions 150 may be formed above and over sidewalls of the associated nanolayer stack 111 so as to make direct contact with the respective end surfaces of the active nanolayers 108 and sacrificial nanolayers 106 therein. Further, the sacrificial S/D regions 150 may be formed over sidewalls of the associated gate spacers so as to make direct contact therewith.

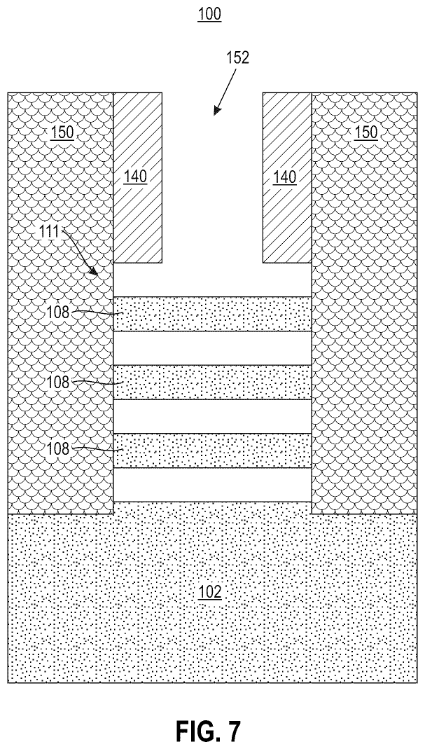

FIG. 7 depicts cross-sectional views of the semiconductor IC device 100 after fabrication operations, in accordance with embodiments of the present disclosure. In the depicted fabrication stages, a gate trench 152 may be formed and the active nanolayers 108 may be released.

In some implementations, the gate trench 152 may be formed by previously conducting a planarization process, such as a chemical mechanical polish (CMP), to remove excess sacrificial S/D region 150 material and to remove the sacrificial gate caps 134 of the sacrificial gate structures 130, thereby exposing the sacrificial gate 132 thereunder.

The gate trench 152 may be formed by the removal of the sacrificial gate structures 130. The sacrificial gate structures 130 may be removed by removing the sacrificial gate 132 and sacrificial gate oxide by a removal technique, such as one or more series of etches. For example, a wet chemical etching process may be used in which one or more chemical etchants remove the sacrificial gate 132 and sacrificial gate oxide of the sacrificial gate structures 130 selective to the active nanolayers 108, gate spacer(s) 140, sacrificial S/D regions 150, STI regions (if applicable), or the like.

The active nanolayers 108 may be released by removing the sacrificial nanolayers 106 that are within the nanolayer stack 111. The sacrificial nanolayers 106 may be removed by a removal technique, such as one or more series of etches that remove the sacrificial nanolayers 106 selective to the active nanolayers 108, gate spacer(s) 140, sacrificial S/D regions 150, STI regions (if applicable), or the like. After the removal of the sacrificial gate structure 130 and the sacrificial nanolayers 106, void spaces may be formed above and/or below the active nanolayers 108 and between the gate spacers 140. In this way, the active nanolayers 108 may be structurally supported by the sacrificial S/D regions 150.

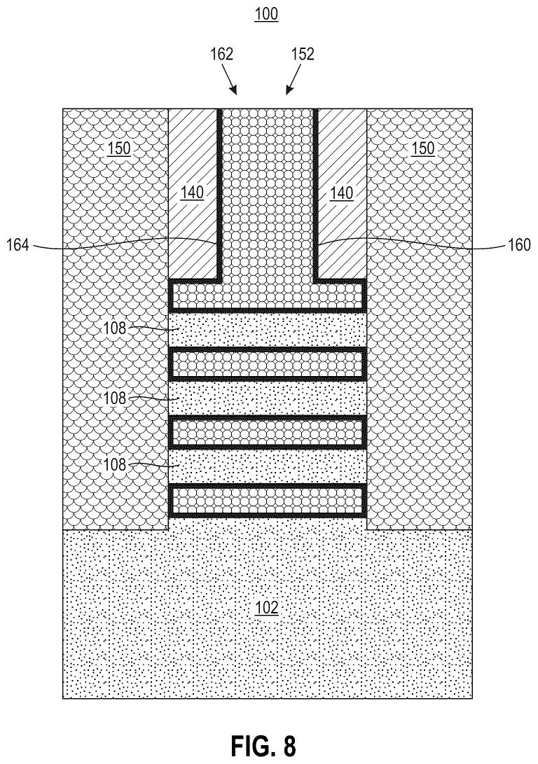

FIG. 8 depicts cross-sectional views of the semiconductor IC device 100 after fabrication operations, in accordance with embodiments of the present disclosure. In the depicted fabrication stages, a high-κ dielectric layer 160 may be formed within the gate trench 152 and a gate trench sacrificial fill 162 may be formed upon the high-κ dielectric layer 160.

The high-κ dielectric layer 160 may be formed by depositing a blanket high-κ dielectric material upon the interior surfaces of the gate trench 152. For example, the high-κ dielectric material may be deposited upon the substrate structure 102, the active nanolayers 108, the sacrificial S/D regions 150, and the gate spacers 140. For clarity, the high-κ dielectric layer 160 may partially fill the void spaces that exist above and/or below the active nanolayers 108 and between the gate spacers 140. A high-κ dielectric material is a dielectric material with a higher dielectric constant than that of SiO₂. The high-κ dielectric layer 160 may be composed of the following illustrative materials: HfLaOₓ, HfAlOₓ, HfSiOₓ, HfZrOₓ, HfTiOₓ, etc. The high-κ dielectric layer 160 can include a single layer or multiple layers, and may be referred to as a liner layer, a wetting layer, and/or an adhesion layer. The thickness of the high-κ dielectric layer 160 may be or may be between, for example, 1-3 nanometers.

The gate trench sacrificial fill 162 may include a liner (not shown) upon the high-κ dielectric layer 160 and a sacrificial dielectric fill material 164 thereupon. Alternatively, the gate trench sacrificial fill 162 may not include a liner and may therefore include the sacrificial dielectric fill material 164 upon the high-κ dielectric layer 160. For clarity, the term gate trench sacrificial fill 162 may be referred to herein to refer to both embodiments (i.e., those that include a liner and sacrificial dielectric fill material and those without the liner). The liner may be a conductive material, such as metal, and may be deposited upon the high-κ dielectric layer 160 within the gate trench 152. In an example, the liner may be composed of Ni, NiPt, Ti, or the like. The sacrificial dielectric fill material 164 may be formed by depositing a blanket dielectric material to fill the remaining gate trench 152. The sacrificial dielectric fill material 164 may be composed of a dielectric material with etch selectivity to the material of the active nanolayers 108. For example, when the active nanolayers 108 are composed of Si, the sacrificial dielectric fill material 164 may be composed of SiGe. In some examples, the sacrificial dielectric fill material 164 may also have etch selectivity with respect to the sacrificial S/D regions 150. For example, the sacrificial S/D regions 150 may a lower percentage of Ge relative to the sacrificial dielectric fill material 164. Subsequently, a planarization process, such as a CMP, may remove excess portions of the high-κ dielectric layer 160 and the gate trench sacrificial fill 162. Therefore, respective top surfaces of the sacrificial S/D regions 150, the gate spacers 140, the high-κ dielectric layer 160, and the gate trench sacrificial fill 162 may be substantially coplanar and/or substantially horizontal.

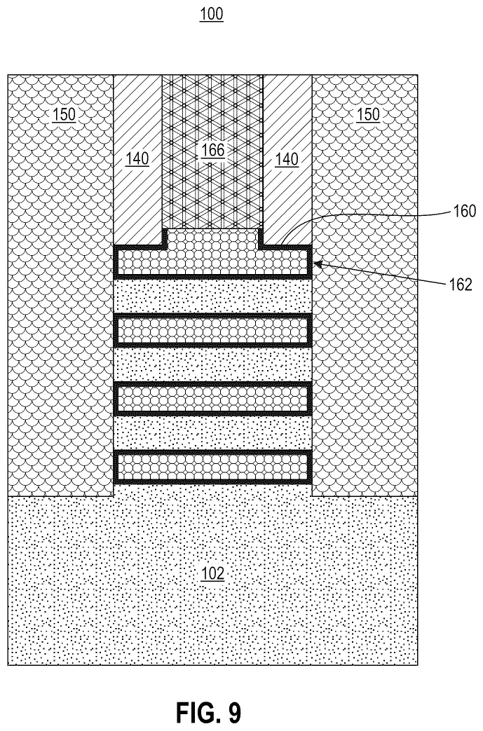

FIG. 9 depicts cross-sectional views of the semiconductor IC device 100 after fabrication operations, in accordance with embodiments of the present disclosure. In the depicted fabrication stages, a sacrificial gate cap 166 is formed between gate spacers 140 over the high-κ dielectric layer 160 and the gate trench sacrificial fill 162.

The sacrificial gate cap 166 may be formed by initially partially removing an upper portion of the high-κ dielectric layer 160 and the gate trench sacrificial fill 162 generally between the gate spacers 140. Such removal may expose the inner sidewalls of the associated gate spacers 140. The high-κ dielectric layer 160 and the gate trench sacrificial fill 162 may be partially removed by an etch process that may be controlled so that the well surface of the etch stops above the bottom surface of the associated gate spacers 140. Consequently, at least a portion of the high-κ dielectric layer 160 may remain on the inner sidewalls of the gate spacers 140, as depicted.

The sacrificial gate cap 166 may be formed by depositing a mask material, such as a hard mask material, such as silicon nitride, silicon oxide, combinations thereof, or the like, upon a remaining portion of the high-κ dielectric layer 160 and gate trench sacrificial fill 162 and upon and between gate spacers 140.

In some examples, the mask material may further be deposited upon the sacrificial S/D regions 150. Subsequently, a planarization process, such as a CMP, may remove excess portions of mask material above the gate spacers 140 and may form the sacrificial gate cap 166. After these fabrication stages, respective top surfaces of the sacrificial S/D regions 150, gate spacers 140, and the sacrificial gate cap 166 may be substantially coplanar and/or substantially horizontal.

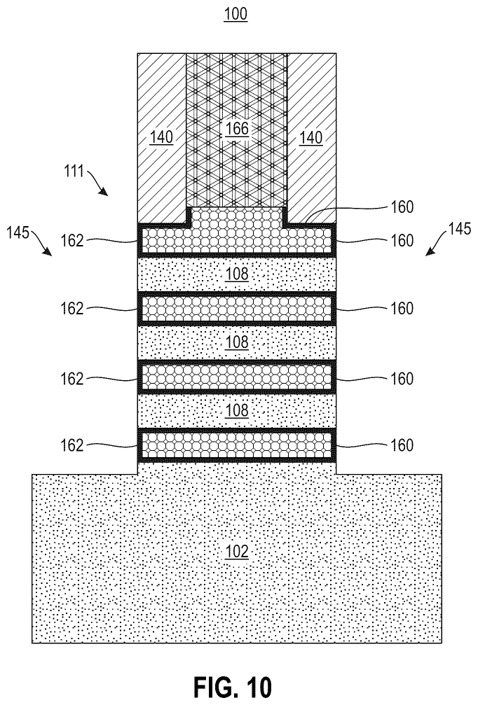

FIG. 10 depicts cross-sectional views of the semiconductor IC device 100 after fabrication operations, in accordance with embodiments of the present disclosure. In the depicted fabrication stages, the sacrificial S/D regions 150 may be removed.

The sacrificial S/D regions 150 may be removed by a removal technique, such as one or more series of etches. For example, such removal may be accomplished by a wet chemical etching process in which one or more chemical etchants are used to remove the sacrificial S/D regions 150 selective to the gate spacers 140, sacrificial gate cap 166, high-κ dielectric layer 160, active nanolayers 108, STI regions, and the substrate structure 102. The removal of the sacrificial S/D regions 150 may reestablish the source/drain canyons 145 and may expose the substrate structure 102 therewith on either side of the active nanolayers 108 of the associated nanolayer stack 111.

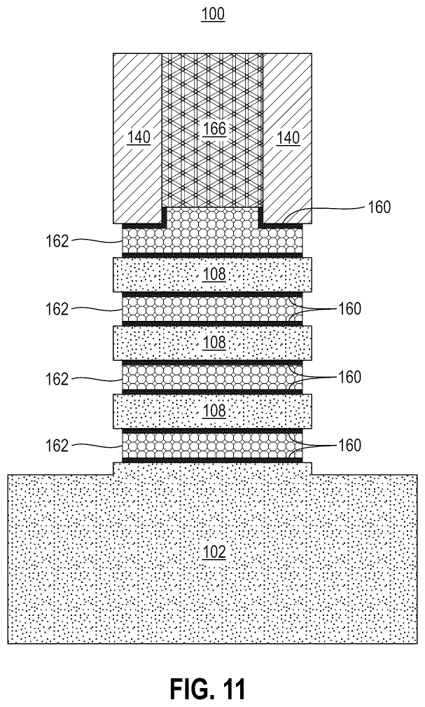

FIG. 11 depicts cross-sectional views of the semiconductor IC device 100 after fabrication operations, in accordance with embodiments of the present disclosure. In the depicted fabrication stages, the exposed portions of the high-κ dielectric layer 160 may be removed.

The exposed portions of the high-κ dielectric layer 160 may be removed by a removal technique, such as one or more series of etches. For example, such removal may be accomplished by a wet chemical etching process in which one or more chemical etchants are used to remove the exposed portions of the high-κ dielectric layer 160 selective to the gate spacers 140, sacrificial gate cap 166, active nanolayers 108, gate trench sacrificial fill 162, STI regions, and the substrate structure 102. The removal of the exposed portions of the high-κ dielectric layer 160 may laterally expose the gate trench sacrificial fill 162.

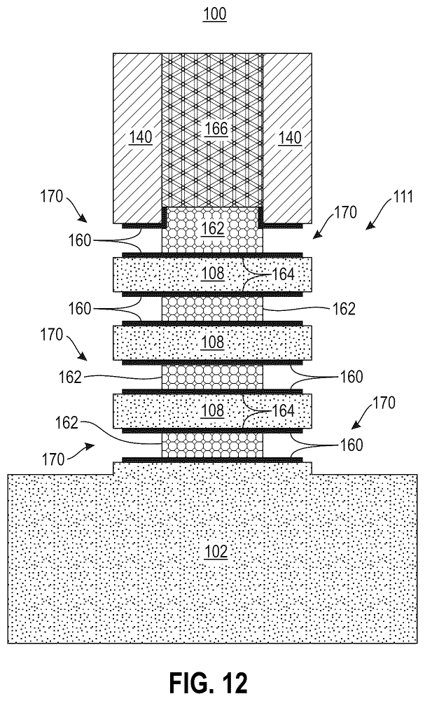

FIG. 12 depicts cross-sectional views of the semiconductor IC device 100 after fabrication operations, in accordance with embodiments of the present disclosure. In the depicted fabrication stages, lateral indents 170 may be formed above and/or below the active nanolayers 108 within the nanolayer stack 111.

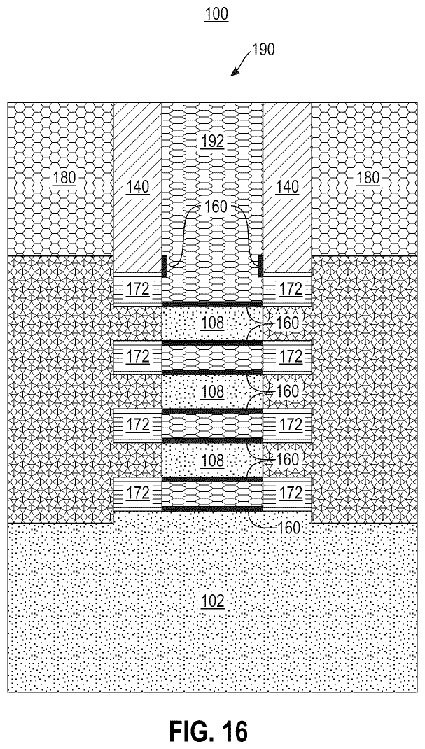

The lateral indents 170 may be fabricated by laterally or horizontally removing respective portions of gate trench sacrificial fill 162 within the nanolayer stack 111. The lateral indents 170 may be formed by a reactive ion etch (RIE) process, which can remove portions of the gate trench sacrificial fill 162. The horizontal depth of the lateral indents 170 may be chosen to set a length for a replacement gate structure 190, shown in FIG. 16. When the sacrificial dielectric fill material 164 of the gate trench sacrificial fill 162 are composed of SiGe and when active nanolayers 108 are Si, the directional RIE can use a boron-based chemistry or a chlorine-based chemistry, for example, which recesses or removes the end portions of the gate trench sacrificial fill 162 (e.g., end portions of the gate trench sacrificial fill 162 generally below spacer 140) selective to the Si active nanolayers 108. In alternative implementations when the sacrificial dielectric fill material 164 of the gate trench sacrificial fill 162 are not SiGe and when active nanolayers 108 are not Si, the directional etch of the gate trench sacrificial fill 162 may generally be selective to the active nanolayers 108, gate spacer(s) 140, STI regions, and/or substrate structure 102. In an example, as depicted, the horizontal well surface of the lateral indents 170 may be substantially coplanar with the inner side surface of the gate spacer 140 there above.

Subsequent to forming the lateral indents 170, respective portions of the high-κ dielectric layer 160 may be retained upon the substrate structure 102 and may be retained upon the top/bottom surface(s) of the active nanolayers 108 within the nanolayer stack 111. Further, portions of the high-κ dielectric layer 160 may be retained upon a bottom surface and a lower portion of the inner side surface of the gate spacers 140. For clarity, at the present fabrication stage, some portions of the high-κ dielectric layer 160 may be exposed within the lateral indents 170. Other portions of the high-κ dielectric layer 160 between active nanolayers 108 and gate trench sacrificial fill 162 may be retained. Similarity, other portions of the high-κ dielectric layer 160 between the gate trench sacrificial fill 162 and the gate spacers 140 may similarly be retained.

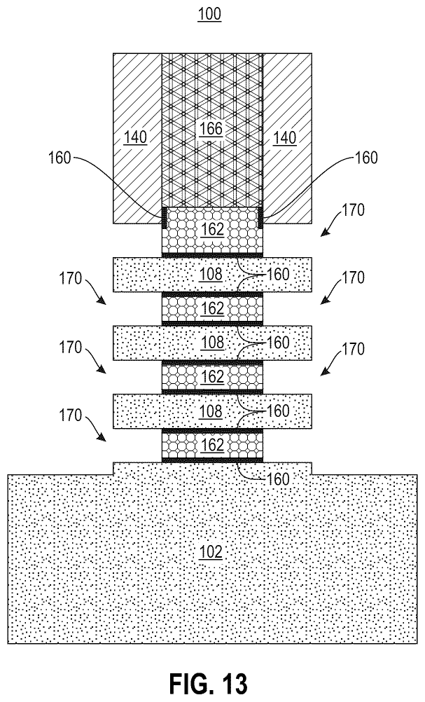

FIG. 13 depicts cross-sectional views of the semiconductor IC device 100 after fabrication operations, in accordance with embodiments of the present disclosure. In the depicted fabrication stages, the exposed portions of the high-κ dielectric layer 160 within the lateral indents 170 may be removed.

The exposed portions of the high-κ dielectric layer 160 may be removed by a removal technique, such as one or more series of etches. For example, such removal may be accomplished by a wet chemical etching process in which one or more chemical etchants are used to remove the exposed portions of the high-κ dielectric layer 160 selective to the gate spacers 140, sacrificial gate cap 166, gate trench sacrificial fill 162, active nanolayers 108, STI regions, and substrate structure 102.

Subsequent to removing the exposed portions of the high-κ dielectric layer 160, the respective protected portions of the high-κ dielectric layer 160 may be retained upon the substrate structure 102 and may be retained upon the top/bottom surface(s) of the active nanolayers 108 within the nanolayer stack 111. Further, the protected portions of the high-κ dielectric layer 160 may be retained at least upon the lower portion of the inner side surface of the gate spacers 140.

The end portions or sidewalls of the retained and protected portions of the high-κ dielectric layer 160 may be substantially coplanar with the associated sidewall of the gate trench sacrificial fill 162 and/or with the inner side surface of the gate spacer 140 there above.

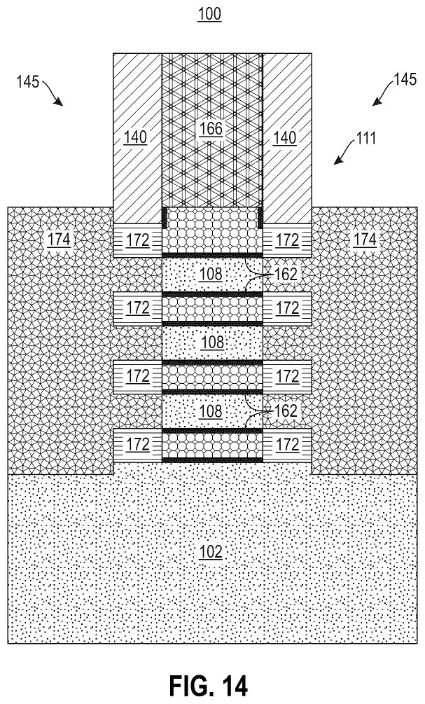

FIG. 14 depicts cross-sectional views of the semiconductor IC device 100 after fabrication operations, in accordance with embodiments of the present disclosure. In the depicted fabrication stages, an inner spacer 172 may be formed within each lateral indent 170 and source/drain (S/D) regions 174 may be formed.

The one or more inner spacers 172 can be formed by ALD or CVD or any other suitable deposition technique that deposits a dielectric material within the lateral indents 170, thereby forming the inner spacers 172. In some examples, the inner spacer(s) 172 are composed of a low-κ dielectric material, which is a material with a lower dielectric constant relative to SiO₂, SiN, SiO, SiBCN, SiOCN, SiCO, etc. or any other suitable dielectric material. For clarity, the inner spacer 172 may be formed directly upon the gate trench sacrificial fill 162 and directly upon the expose side or end surfaces of the associated high-κ dielectric layers 160. An inner spacer 172 may be formed directly upon the bottom surface of the associated gate spacer 140. Similarly, an inner spacer 172 may be formed directly upon the substrate structure 102.

The respective S/D regions 174 may be formed upon the substrate structure 102 within the source/drain canyon 145. The S/D regions 174 may be formed in a sequential process so that, for example, p-doped S/D regions 174 may be formed in a first formation sequence and then n-doped S/D regions 174 may be formed in a second formation sequence, or vice versa.

Each S/D region 174 may form either a source or a drain, respectively, of a respective transistor and is connected to respective end surfaces of the active nanolayers 108 of one or more nanolayer stacks 111. Each S/D region 174 may be composed of a semiconductor material and a dopant. As used herein, a “source/drain” region can be a source region or a drain region depending on subsequent wiring and application of voltages during operation of the applicable transistor.

The semiconductor material that provides each of the S/D regions 174 may be composed of one of the semiconductor materials mentioned above for the semiconductor structure 102. For example, the semiconductor material that provides the S/D region 174 can be compositionally the same, or compositionally different from each active nanolayer 108. The dopant that is present in the S/D regions 174 can be either a p-type dopant or an n-type dopant. The term “p-type” refers to the addition of impurities to an intrinsic semiconductor that creates deficiencies of valence electrons. “n-type” refers to the addition of impurities that contributes free electrons to an intrinsic semiconductor. When the semiconductor material is doped with a p-type dopant, the resulting S/D regions 174 are referred to herein as being p-doped and when the semiconductor material is doped with a n-type dopant, the resulting S/D regions 174 are referred to herein as being n-doped.

The S/D regions 174 may be epitaxially grown or formed. In some examples, the S/D regions 174 are formed by in-situ doped epitaxial growth. The use of an in-situ doping process is merely an example. For instance, one may instead employ an ex-situ process to introduce dopants into the S/D regions 174. Other doping techniques can be used to incorporate dopants in the S/D regions 174.

In some examples, the epitaxial growth that forms the S/D region 174 occurs or is promoted from the upper surface of the substrate structure 102 and from the exposed sidewalls of the active nanolayers 108, or the like, while epitaxial growth may be limited or does not occur from the STI regions (e.g., that exist into and/or out of the page) that neighbor the source/drain canyons 145. For clarity, the S/D region 174 is formed to directly connect to the side or end surfaces of the active nanolayers 108.

In an example, the top surface of the S/D regions 174 may be below the bottom surface of the sacrificial gate cap 166 to allow for the sacrificial gate cap 166 to be removed by a planarization technique so as to expose the underlying gate trench sacrificial fill 162 without also exposing the S/D regions 174.

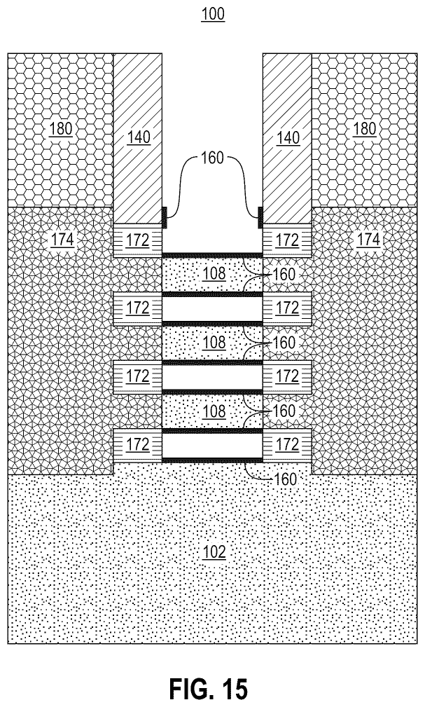

FIG. 15 depicts cross-sectional views of the semiconductor IC device 100 after fabrication operations, in accordance with embodiments of the present disclosure. In the depicted fabrication stages, an interlayer dielectric (ILD) 180 may be formed and the sacrificial gate cap 166 and the gate trench sacrificial fill 162 may be removed.

The ILD 180 may be formed by depositing a blanket dielectric material over the S/D region(s) 174, over the STI regions, over the sacrificial gate cap 166, over the gate spacer(s) 140, and the like. The ILD 180 can be composed any suitable dielectric material, such as, for example, porous silicates, carbon doped oxides, silicon dioxides, silicon nitrides, silicon oxynitrides, or other dielectric materials. A planarization process, such as a CMP, may be performed to remove excess ILD 180 material and to remove the sacrificial gate cap 166, thereby exposing the gate trench sacrificial fill 162 thereunder.

The gate trench sacrificial fill 162 may be removed by a removal technique, such as one or more series of etches. For example, a wet chemical etching process may be utilized in which one or more chemical etchants are used to remove the gate trench sacrificial fill 162 selective to the active nanolayers 108, inner spacers 172, gate spacer(s) 140, high-κ dielectric layers 160, STI regions, or the like. The gate trench sacrificial fill 162 removal may effectively release the active nanolayers 108. After the removal of gate trench sacrificial fill 162, void spaces may be formed above and/or below the high-κ dielectric layers 160 that are directly upon active nanolayers 108.

For clarity, at the present fabrication stage, the high-κ dielectric layers 160 that are directly upon active nanolayers 108 may be maintained. Further, one or more residual portions of the high-κ dielectric layers 160 that are directly upon the inner sidewall of the gate spacers 140 may likewise be maintained. Further, because the high-κ dielectric layers 160 are formed upon the active nanolayers 108 prior to the formation of the associated replacement gate structure 190, depicted in FIG. 16, such fabrication process flow may be referred to as a high-κ first process.

FIG. 16 depicts cross-sectional views of the semiconductor IC device 100 after fabrication operations, in accordance with embodiments of the present disclosure. In the depicted fabrication stages, the replacement gate structure 190 may be formed.

The replacement gate structure 190 may be formed in place of the removed gate trench sacrificial fill 162 upon the high-κ dielectric layers 160 and around the released active nanolayers 108, upon STI regions, upon the substrate structure 102, etc. The replacement gate structure(s) 190 may be formed by forming an interfacial layer on the gate spacer(s) 140, on the high-κ dielectric layers 160, on the substrate structure 102, on the inner spacers 172, etc. that are interior to and/or upon the respective surfaces interior to the opening created by the removal of the gate trench sacrificial fill 162.

The replacement gate structure(s) 190 may be formed by depositing a work function (WF) gate 192 upon the high-κ dielectric layers 160, upon the gate spacers 140, and upon the inner spacers 172. The WF gate 192 can be comprised of a conductor, such as a metal. In general, the WF gate 192 may set the threshold voltage (Vt) of the semiconductor IC device 100. The high-κ dielectric layers 160 may separate the WF gate 192 from the nanolayer channel (i.e., the active nanolayers 108). Other metals that may be desired to further fine tune the effective work function (eWF) and/or to achieve a desired resistance value associated with current flow through the replacement gate structure 190.

In some examples, the replacement gate structure(s) 190 may be further formed by depositing a conductive fill gate (not shown) upon the WF gate 192. The conductive fill gate can be comprised of a conductor material and/or metal, such as but not limited to, e.g., tungsten, aluminum, ruthenium, rhodium, cobalt, copper, tantalum, titanium, or the like. After the replacement gate structure 190 formation, the top surface of the semiconductor IC device 100 may be planarized by a planarization technique such as a CMP, mechanical grinding process, or the like. Consequently, respective to surfaces of the ILD 180, the gate spacers 140, and the replacement gate structure 190 may be substantially horizontal and/or substantially coplanar.

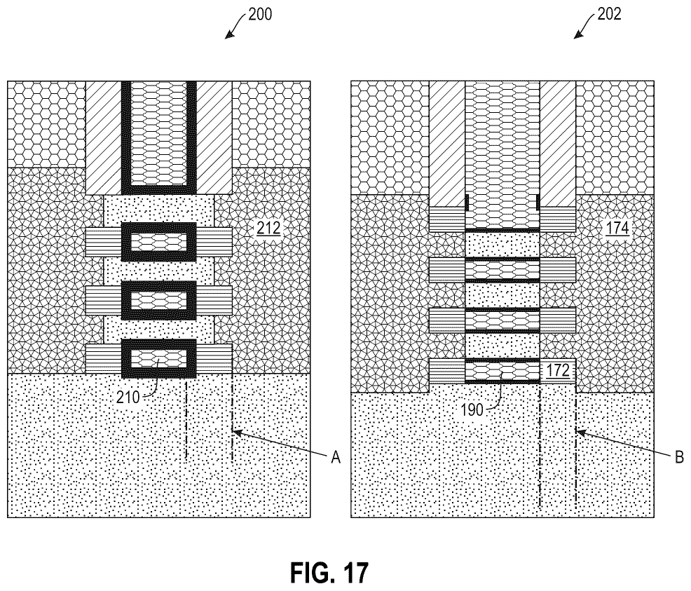

FIG. 17 depicts respective cross-section views of a nanolayer transistor 200 and a nanolayer transistor 202 in which the high-κ dielectric is absent from a sidewall of the inner spacer 172. Consequently, the inner spacer 172 is able to be directly connected with the replacement gate structure 190. Therefore, a horizontal dimension B of dielectric material between the source/drain region 174 and the replacement gate structure 190 may be reduced relative to a similar dimension A of dielectric material between source/drain region 212 and gate structure 210. Consequently, the parasitic capacitance between the source/drain region 174 and the replacement gate structure 190 may be relatively reduced which may improve the performance of the nanolayer transistor 202 and may provide for further associated semiconductor IC device scaling.

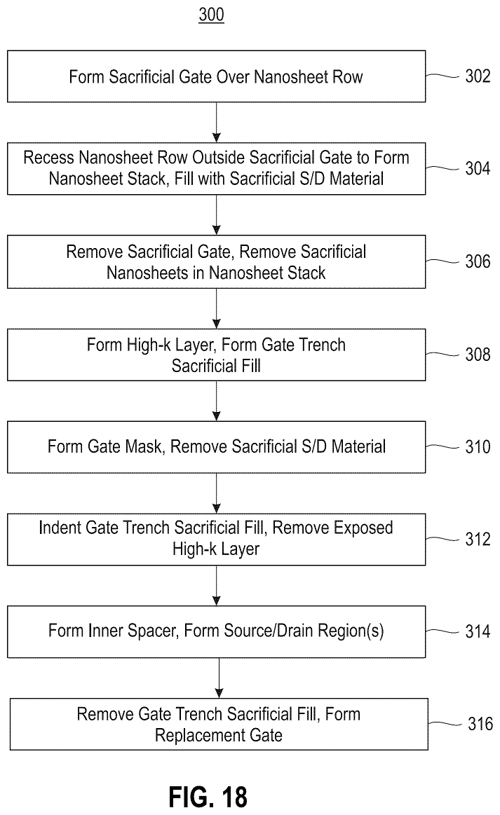

FIG. 18 depicts a flow diagram illustrating a method 300 to fabricate a semiconductor IC device, such as semiconductor IC device 100. The depicted fabrication operations of method 300 are illustratively depicted and described above with reference to one or more of FIG. 3 through FIG. 17 of the drawings, which describe the fabrication of semiconductor IC device 100, though the fabrication operations described in method 300 may be used to fabricate other types of semiconductor IC devices. The method 300 depicted herein is illustrative. There can be many variations to the diagram or operations described therein without departing from the spirit of the embodiments. For instance, the operations can be performed in a differing order, or operations can be added, deleted, or modified.

At block 302, method 300 may begin with forming a sacrificial gate over a nanosheet row. For example, a sacrificial gate structure 130 is formed over a nanosheet row 109 and upon a substrate structure 102.

At block 304, method 300 may continue with recessing the nanosheet row outside of the sacrificial gate to form a nanosheet stack and may further continue with filling a recess with sacrificial S/D material. For example, the nanosheet row 109 is split into multiple nanosheet stacks 111 by removing the nanosheet row 109 between sacrificial gate structure 130. Further, source/drain canyons 145 may be formed in association with the nanosheet stack 111 formation and the source/drain canyons 145 may be filled to form sacrificial S/D regions 150.

At block 306, method 300 may continue with removing the sacrificial gate and with removing the sacrificial nanosheets within the nanosheet stack. For example, the sacrificial gate structure 130 and the sacrificial nanolayers 106 may be removed from the nanosheet stack 111.

At block 308, method 300 may continue with forming a high-κ layer and with forming a gate trench sacrificial fill. For example, high-κ dielectric layer 160 is formed upon the active nanolayers 108 within the nanosheet stack 111. Subsequently, the gate trench sacrificial fill 162 may be formed upon the high-κ dielectric layer 160.

At block 310, method 300 may continue with forming a gate mask and with removing the sacrificial S/D material. For example, sacrificial gate cap 166 is formed and the sacrificial S/D regions 150 are removed.

At block 312, method 300 may continue with indenting the gate trench sacrificial fill and removing the portions of the high-κ layer that are exposed by such removal. For example, lateral indents 170 may be formed by indenting the gate trench sacrificial fill 162 and the portions of the high-κ dielectric layer 160 that are exposed by such indenting may be removed.

At block 314, method 300 may continue with forming inner spacers and with forming S/D regions. For example, inner spacer 172 is formed within the lateral indent 170 and the S/D region 174 is formed against the active nanolayers 108 within the nanosheet stack 111.

At block 316, method 300 may continue with removing the gate trench sacrificial fill and with forming a replacement gate. For example, gate trench sacrificial fill 162 is removed and replacement gate structure 190 is formed in place thereof.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor integrated circuit (IC) device comprising:
a replacement gate structure comprising a work function gate;
a high-κ layer directly connected with and between the work function gate and a nanolayer channel; and
an inner spacer directly connected to the work function gate.

2. The semiconductor IC device of claim 1, further comprising:
a source/drain region directly connected with the nanolayer channel and directly connected to the inner spacer.

3. The semiconductor IC device of claim 2, further comprising:
a gate spacer upon and directly connected to the inner spacer.

4. The semiconductor IC device of claim 3, further comprising:
a residual portion of the high-κ layer directly upon a lower sidewall portion of the gate spacer between the gate spacer and the work function gate.

5. The semiconductor IC device of claim 4, wherein an upper sidewall portion of the gate spacer is directly connected to the work function gate.

6. The semiconductor IC device of claim 3, wherein the inner spacer comprises an inner sidewall that is directly connected to the work function gate.

7. The semiconductor IC device of claim 6, wherein the inner spacer comprises an outer sidewall and a bottom surface that is directly connected to the source/drain region.

8. The semiconductor IC device of claim 7, wherein the inner spacer comprises a top surface that is directly connected to the gate spacer.

9. The semiconductor IC device of claim 7, wherein the bottom surface of the inner spacer is substantially coplanar with a top surface of the nanolayer channel.

10. The semiconductor IC device of claim 2, wherein the inner spacer separates the work function gate from the source/drain region.

11. A semiconductor integrated circuit (IC) device comprising:
a high-κ layer directly connected to a top surface, to a bottom surface, to a front surface, and to a rear surface of a nanolayer channel;
a work function gate directly connected to the high-κ layer; and
an inner spacer comprising a bottom surface that is substantially coplanar with the top surface of the nanolayer channel and an inner sidewall that is directly connected to the work function gate.

12. The semiconductor IC device of claim 11, further comprising:
a source/drain region directly connected to a side surface of the nanolayer channel and directly connected to the bottom surface of the inner spacer.

13. The semiconductor IC device of claim 12, further comprising:
a gate spacer directly connected to a top surface of the inner spacer.

14. The semiconductor IC device of claim 3, further comprising:
a residual high-κ layer portion upon a lower sidewall portion of the gate spacer and directly between the gate spacer and the work function gate.

15. The semiconductor IC device of claim 14, wherein an upper sidewall portion of the gate spacer is directly connected to the work function gate.

16. The semiconductor IC device of claim 15, wherein the inner spacer further comprises an outer sidewall that is directly connected to the source/drain region.

17. The semiconductor IC device of claim 12, wherein the inner spacer separates the work function gate from the source/drain region.

18. A semiconductor integrated circuit (IC) device fabrication method comprising:
forming a high-κ layer within the gate trench around one or more active nanolayers;
forming a gate trench sacrificial fill upon the high-κ layer filling the gate trench; and
recessing a portion of the gate trench sacrificial fill and forming a gate mask in place thereof.

19. The semiconductor IC device fabrication method of claim 18, further comprising:
forming a sacrificial gate over a nanolayer row;
recessing the nanolayer row outside of the sacrificial gate to form a nanolayer stack;
forming a sacrificial source/drain region within the recess against the nanolayer stack;
forming a gate trench by removing the sacrificial gate and removing one or more sacrificial nanolayers within the nanolayer stack;
removing the sacrificial source/drain region;
laterally indenting the gate trench sacrificial fill; and
removing exposed portions of the high-κ layer and retaining the high-κ layer that is protected by the gate trench sacrificial fill and that is around the one or more active nanolayers.

20. The semiconductor IC device fabrication method of claim 19, further comprising:
forming an inner spacer within the lateral indent;
forming a replacement source/drain region against the one or more active nanolayers; and
removing the gate trench sacrificial fill and forming a replacement gate in place thereof upon the high-κ layer that is around the one or more active nanolayers and upon the inner spacer.
